(19) United States
(12) Patent Application Publication
(10) Pub. No.: US 2005/0040037 A1
(43) Pub. Date: Feb. 24, 2005

(54) Electron beam enhanced large area deposition system

(76) Inventors: Scott G. Walton, Burke, VA (US); Darrin Leonhardt, Gaithersburg, MD (US); Robert A. Meger, Crofton, MD (US); Richard Fernsler, Annandale, VA (US); Christorpher Muratore, Alexandria, VA (US)

Correspondence Address: NAVAL RESEARCH LABORATORY;ASSOCIATE COUNSEL (PATENTS), CODE 1008.2, 4555 OVERLOOK AVENUE, S.W., WASHINGTON, DC, 20375-5320, US

(21) Appl. No.: 10/644,567

(22) Filed: Aug. 20, 2003

(51) Int. Cl. C23C 14/32

(52) U.S. Cl. 204/298.06; 204/298.16; 204/298.19

(57) ABSTRACT

This invention provides a means to deposit thin films and coatings on a substrate using an electron beam generated plasma. The plasma can be used as an ion source in sputter applications, where the ions are used to liberate material from a target surface which can then condense on a substrate to form the film or coating. Alternatively, the plasma may be combined with existing deposition sources including those based on sputter or evaporation techniques. In either configuration, the plasma serves as a source of ion and radical species at the growing film surface in reactive deposition processes. The electron beam large area deposition system (EBELADS) is a new approach to the production of thin films or coatings up to and including several square meters.

### BACKGROUND OF THE INVENTION

1. Field of the Invention

This invention provides a means to produce large-area thin films and coatings. Thin films and coatings have applications in manufacturing, optics, and the semiconductor industries. Hard coatings can be used in tool manufacturing or for materials subject to high friction environments while corrosion resistant coatings can extend the lifetime of materials exposed to harsh chemical environments. Thin films can selectively increase or decrease the optical transmission properties of glass. In the semiconductor industry, thin films can be employed as a diffusion barrier between incompatible materials used in integrated circuit production.

This invention utilizes an electron beam-produced plasma capable of generating ion and radical fluxes over large areas. The system can be configured as a large-area sputter source where the plasma ions are used to sputter (or remove) material from a target. This material then condenses on a substrate to form the film or coating. The plasma also serves as a source of ions and radicals that can be delivered, in conjunction with the target material, to a growing film surface. Alternatively, the electron beam-generated plasma can be combined with existing deposition techniques including sputter or evaporation sources. In either configuration, the electron beam enhanced large area deposition system (EBELADS) is a new approach to the production of thin films and coatings over areas up to and exceeding several square meters.

2. Description of Prior Art

There are numerous methods by which films and coatings are deposited on substrates, but can be grouped into two general categories: physical vapor deposition (PVD) and chemical vapor deposition (CVD) techniques. In both cases, the process involves the production of a vapor that is then allowed to condense on a substrate to form the film or coating. Plasmas are often incorporated into both techniques because of their ability to enhance the processes by providing energetic and/or reactive species not attainable by other methods. Thus, the inclusion of plasmas is referred to as plasma-enhanced physical vapor deposition (PEPVD) or plasma-enhanced chemical vapor deposition (PECVD). In fact, plasmas are favored for PVD techniques that utilize the sputtering of material from a target because of their ability to deliver a large flux of energetic ions to the target. Such techniques include the use of planar diodes and triodes, as well as magnetron sputtering sources.

Sputtering is one of the most common techniques used in the production of thin films and coatings. Sputtering broadly describes the liberation of material from a surface by energetic ions, where the ejected materian is predominately neutral ions. The energetic ions are often provided by a plasma discharge that is driven by applying a dc or rf voltage to the target. The removal rate of target material increases with increasing ion flux and incident ion energy, which is largely controlled by the applied target bias. In sputtering based systems, the ejected material, predominately neutral atoms, is then allowed to condense on a remotely located substrate to form the film or coating. The substrate is usually located opposite the target and the neutral flux must first pass through the plasma discharge en route to the substrate, which can lead to a partial ionization of the neutral vapor. Therefore, both neutral and ionized target material, as well as ions, electrons and radicals from the plasma bombard the growing film.

The types of films that can be produced by sputter deposition vary widely and include simple metals, metal nitrides and oxides, and semiconductors and non-conducting materials. Film quality is usually determined by the substrate temperature and by the type and energy of the bombarding particle. The particle type can be varied by adjusting the location of the substrate relative to the target or by introducing an auxiliary or secondary plasma located close to the substrate. Either approach can be used to alter the relative fluxes of ions and radicals striking the substrate. Increasing the incident ion energy, usually accomplished by applying a bias to the substrate, increases packing density and yields films with electronic and mechanical properties similar to those found in bulk material.

The most common PVD tool is the magnetron. A magnetron is comprised of a target that can be biased (dc or rf) to some 100's of volts and a series of magnets located behind the target. A discharge is driven by the applied bias and the magnets are arranged to produce a region of high magnetic field near the target surface. The large field partially confines the plasma electrons, improving the ionization efficiency, and allows for the formation of a high-density plasma near the surface using relatively low voltages and pressures. Magnetron systems are thus characterized by large sputtering and deposition rates. However, the magnetic field needed for confinement limits the plasma to an annular ring at the surface and the erosion pattern produced by such a ring results in poor target utilization and therefore wasted target material. Target utilization is much better in dc or rf diodes. Diodes are parallel plate, capacitive discharges where the target is the cathode and the substrate is located on the anode. Improved utilization results because the plasma is uniform over the target area. In these sources, the ionization efficiency is comparatively low and so higher operating pressures are required to get reasonable sputtering rates. Unfortunately, high pressure leads to lower growth rates and often poor film quality. For either magnetron or diode systems, scaling up to large areas (>1 m²) while retaining good film uniformity and quality is not easily achieved.

### SUMMARY OF THE INVENTION

Over the last few years, the Charged Particle Physics Branch (Code 6750) at the Naval Research Laboratory has developed a new plasma source called the Large Area Plasma Processing System (LAPPS). See U.S. Pat. Nos. 5,182,496 and 5,874,807 and the following articles for background material. Physics of Plasmas, 5(5), 2137-2143, 1998; Plasma Sources Sci. Technol, 9, 370-386, 2000; Journal of Vacuum Science and Technology A, 19(4), 1325-1329,2001; Journal of Vacuum Science and Technology A, 19(4), 1367-1373, 2001; Physics and Plasma, 8(5), 2558-2564, 2001. All patents and articles cited above are incorporated herein by reference in their entireties. This device uses a magnetically confined, sheet electron beam to ionize a background gas and produce a planar plasma. Electron beams exhibit high ionization and dissociation efficiency of the background gas. In addition, the plasma production process is largely independent of the gas constituents and reactor geometry, allowing for both plasma and system optimization. Since the plasma volume is limited only by the beam dimensions, the usable surface area of these plasmas can exceed that of other plasma sources. In our laboratory, rectangular plasmas with a thickness of 1 cm and an area of 1 m² have been produced. The electron beam can be generated from a linear hollow cathode, hot filament, or field emitting electron source.

Plasmas produced in this manner are attractive for thin film and coating processes and can be utilized in many ways. One way is as an ion source for sputter deposition. Alternatively, the beam-generated plasma could be used in conjunction with existing PVD technologies such as sputter sources or evaporation techniques. In either configuration, electron beam-produced plasmas offer higher uniformity, efficiency, and potentially unique chemistries relative to conventional sources. This combination of features and the ability to scale to large areas adds a range of control variables that would enable the system to access operating regimes not possible with conventional deposition technologies. Throughout this description the terms film or thin film also includes coatings.

### FIGURES

FIG. 1. is a schematic representation of the EBELADS configured to include a large area sputtering source. In this configuration, the beam-generated plasma provides both ions for sputtering and delivers useful reactive species to the growing film.

FIG. 2. is a schematic representation of the EBELADS employing existing PVD technology such as a magnetron.The electron beam produced plasma is located between the material source and substrate and provides improved process control and a variable ion flux to the growing film.

FIG. 3. shows atomic force micrographs of TiN films and illustrates an improved film morphology using the improved EBELADS configuration of FIG. 2, where one magnetron was employed as the material source. The EBELADS results are compared to the case where only a magnetron is used. Each sample is subject to the same bias and time-averaged ion bombardment. Films produced using EBELADS exhibit larger grain size, which are indicative of higher surface mobility of the plasma species contributing towards film growth, , J. Appl. PHYS., 62, 1796, 1987. Films produced under higher mobility conditions are expected to exhibit denser microstructures and improved mechanical and electronic properties.

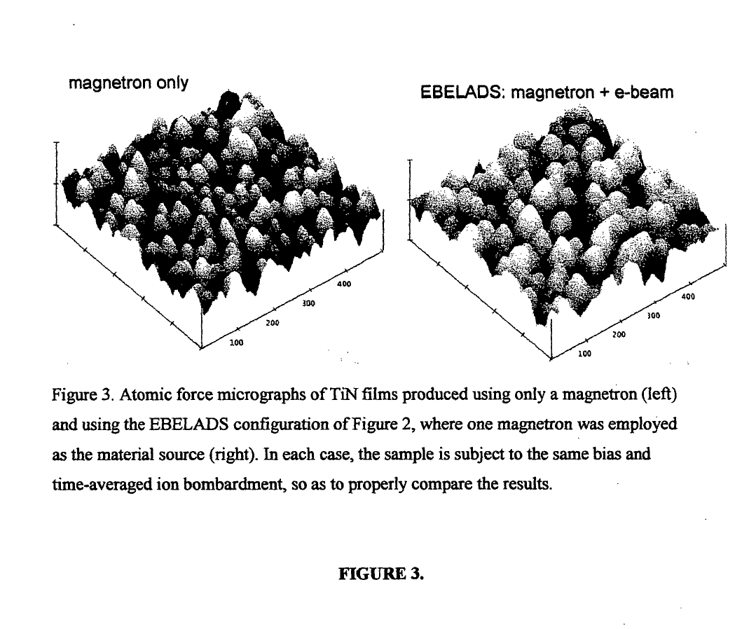

### DETAILED DESCRIPTION OF THE INVENTION

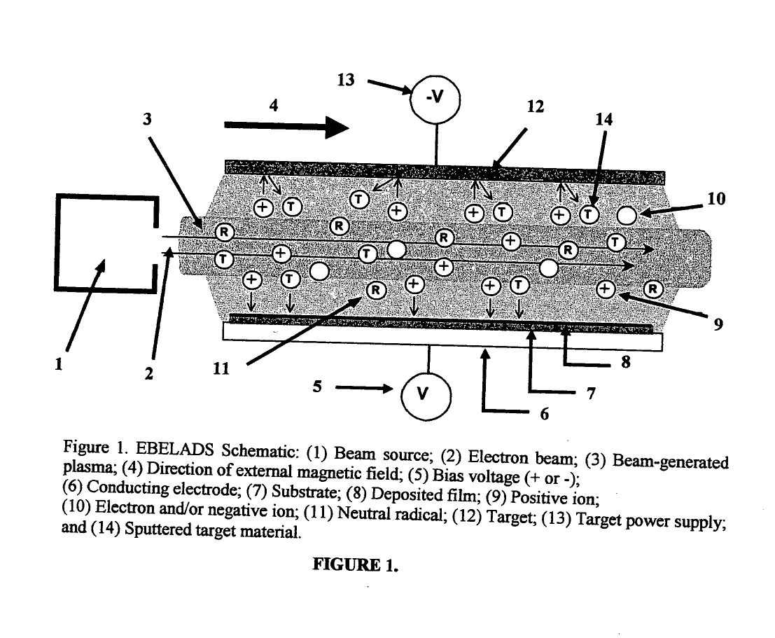

EBELADS is similar to LAPPS in concept and is illustrated in FIGS. 1. and 2. Specifically, EBELADS uses a magnetically confined, sheet electron beam to ionize and dissociate a background gas. The electron beam energy is nominally a few kiloelectron volts (keV) or less with beam current densities ranging from 1 to 100 mA/cm² over the cross-section of the beam. The beam width is variable and can exceed a meter. The thickness is up to a few centimeters and is maintained over the beam length by an axial magnetic field that exceeds 100 Gauss. The length of the plasma sheet is determined by the range of the electron beam, and scales with the beam energy and gas pressure. The range is usually maintained at several times the system length to ensure uniformity in plasma production. The gas pressure typically lies between 10 and 100 mTorr. For the parameters outlined, the beam range is greater than 1 m and the plasma densities are as high as ˜10¹² cm⁻³. Thus, the EBELADS system is capable of producing thin films and coatings over areas up to and exceeding 1 m². While the method of plasma production in EBELADS and LAPPS is the same, the EBELADS system is optimized for the production of thin films and coatings and results in a fundamentally different device. Electron beam-produced plasmas are characterized by low electron temperatures, with energies extending from a few tenths of an eV in molecular gases to about one eV in noble gases. The plasma potential is approximately five times the electron temperature and so the plasma potential extends up to 5 or 6 volts, depending on the electron temperature. For unbiased surfaces then, incident ions will impact the surface with energies up to the plasma potential(a few eV). For a plasma density of 10¹¹ cm⁻³, the flux of ions at a surface will be on the order of 10¹⁶ cm⁻²s⁻¹. Furthermore, the plasma density is found to be uniform over the electron beam volume resulting in a uniform flux that is deliverable over areas exceeding a square meter.

As noted, the EBELADS system can be operated in multiple configurations. In one configuration, the electron beam-generated plasma serves as an ion source for sputtering material from a target, as shown in FIG. 1. The beam-generated plasma is produced adjacent to the target. Candidate target materials include metals, alloys, and semiconductors. Ions diffuse out of the plasma and impact the target with low energies, in the absence of any bias. In order to increase the ion energies above the sputtering threshold, the target must be biased with either a dc or rf voltage. The latter would be required for non-conducting targets such as those comprised of semiconductor material. The plasma sheet should be somewhat larger than the target, so that the target is sputtered uniformly over its surface area. The plasma sheet is located between the target and the substrate, and the locations of each can be adjusted to control the relative and absolute flux of ions and radicals reaching the target or substrate.

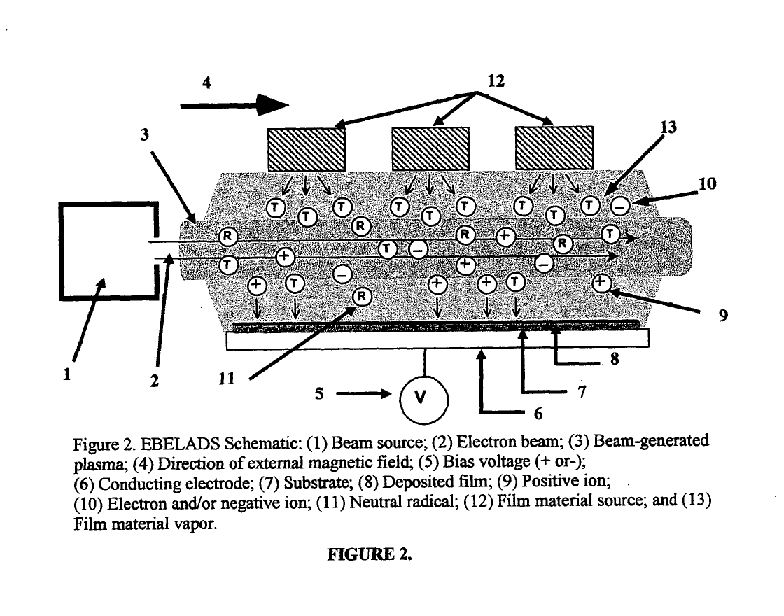

A second EBELADS configuration combines the electron beam plasma source with existing PVD technologies where the electron beam-produced plasma is located between the material source and substrate as shown in FIG. 2. Depending on the desired process, either sputtering or evaporation sources can be used while the number of sources and source material can vary. Sputtering sources include magnetrons and ion beams. Electron beams, lasers, and thermal means can be employed to evaporate material into the gas phase. Here again, the relative position of the beam, material source, and substrate may be independently set.

In any configuration, the working gas can range from single atomic species such as argon to mixtures of atomic and/or molecular gases. For reactive sputter deposition, small quantities of molecular gases such as nitrogen or oxygen would be added to the feedstock gas. Applying a dc or rf bias to the substrate can increase the incident ion energies at the substrate, if higher energies are required.

The advantages and new features of the device relate to the unique properties of electron beam generated plasmas. In particular, the source improves the efficiency and uniformity in plasma production, provides greater control over plasma production, expands the ability to control the particle fluxes at surfaces, offers new and alternative chemical pathways, and increases the effective usable target and deposition areas.

Consider first the ability to regulate the concentrations of plasma species. In conventional rf or dc discharge sources, gas ionization and dissociation favors the species with the lowest ionization and dissociation energies and thus these sources provide little control over the relative concentrations of plasma species. High-energy electron beams, on the other hand, create ion and radical species roughly in proportion to the relative gas concentrations, since the electron beam energy is well above the threshold for ionization and dissociation. The resulting production and thus concentration of species is markedly different than other plasma sources, and allows for a unique set of gas phase and surface chemistries. The beam current, operating pressure, and gas mixture ratios determine the total and relative production rates. These variables allow for control over the production of ion and radical species and ultimately over the flux of these species at the target and substrate.

Control over the flux of plasma species is further enhanced due to the fact that plasma production is relatively de-coupled from reactor geometry so that the target and/or substrate can be independently located. In electron beam-generated plasmas, the ionization region is confined to the beam volume, and because the beam can be collimated by a magnetic field, the plasma production volume can be well defined and localized. The electron beam, for example, can be positioned at a variable distances from a substrate surface. Increasing the plasma-to-substrate distances decreases the ion flux while having little effect on the neutral fluxes.

Another advantage of electron beam produced plasmas is the inherently low plasma electron temperatures. The electron temperature governs both the plasma chemistry and the energies at which ions impact the surfaces and in electron beam produced plasmas. The electron temperature rarely exceeds 1 eV. In other sources, the electron temperature ranges between 5 and 10 eV. The benefit of the reduced energies is threefold; first, sputtering is greatly diminished at the growing film surface since the incoming ion energies rarely exceed the surface binding energies of most species. Second, for processes requiring higher energies, like sputtering, the incident ion energy maybe increased by applying a bias. When the electron temperature is low, the variation in the incident ion energy about the applied bias is small (typically a few eV). This allows for the use of a wide variety of target materials, from hard metals that require 100's of eV to more delicate organic material that requires only 10's of eV. Third, a low electron temperature reduces the rates at which unwanted changes in plasma chemistry occur.

There is no fundamental limit on the physical dimensions of the electron beam and the efficiency and uniformity in plasma production remain constant over the beam volume. With other plasma sources, scaling to large areas and maintaining uniformity over the plasma volume is difficult and so using the electron beam-produced plasmas offer distinct advantages. Scaling up in length and width is straightforward. The cross-section of the beam (width and thickness) is determined by the electron beam source while the length of the beam varies with both beam energy and gas pressure. In our laboratory, plasma sheets with surface areas from 100's to over 10,000 cm² have been produced in a variety of gases. The effective processing area is nearly identical to the plasma surface area. Uniform, large area plasma sources can be especially useful in sputter applications. Not only is sputtering over large areas possible but the entire surface area of a target can be utilized, reducing wasted target material. The inherent scalability and uniformity are also attractive when combining electron beam sources with existing deposition technologies. For example, such a source could be combined with multiple magnetron sources for large area deposition applications. With no restrictions on the dimensions of the plasma source, uniform, large area depositions are possible.

A number of devices are currently capable of producing thin films and coatings. These include magnetrons, dc and rf-diodes, cathodic arcs, and those based on evaporation techniques. However, none of these devices posses all of the features listed above for the EBELADS. The EBELADS is the first device that combines high efficiency, large area possibilities, and broad process control in a single device

1. A large area plasma deposition system, comprising:
A. an electron beam source having a width much larger in dimension than its thickness;
B. a plasma sheet produced by said electron beam passing through a gas; said plasma being a low electron temperature plasma sheet of pre-determined width, length, thickness, and location relative to a surface;
C. magnetic means for confining said beam so as to produce a geometrically well defined, spatially uniform plasma sheet;
D. a target comprising a material source for thin films or coatings;
E. a substrate upon which material sputtered from said target by said plasma is deposited as a thin film or coating:

2. The system according to claim 1, wherein said target is electrically biased above a sputtering threshold for said material source.

3. The system according to claim 2, wherein said electrical bias is selected from DC or RF sources.

4. The system according to claim 1, wherein said substrate is electrically biased.

5. The system according to claim 4, wherein said electrical bias is selected from DC or RF sources.

6. The system according to claim 1, wherein the relative position of said beam, plasma, target and substrate is adjustable.

7. The system according to claim 1, wherein said film or coating material source is selected from the group consisting of metals, alloys, semiconductors or non-conducting materials.

8. The system according to claim 1, wherein said electron beam source is selected from the group of sources consisting of a linear hollow cathode beam source, hot filament or field emitting electron source.

9. The system according to claim 1, wherein said gas is selected from the group consisting of atomic or molecular gases or mixtures thereof.

10. The system according to claim 1, wherein both target and substrate are electrically biased.

11. A hybrid large area plasma deposition system, comprising:
A. the electron beam plasma system defined in steps A. through C. of claim 1;
B. in conjunction with said plasma system, a conventional physical vapor deposition (PVD) system for generating material for coating or deposition on a substrate, said materials being generated from a film material source by sputtering means or vaporization means.

12. The hybrid system of claim 13, wherein said sputtering means is selected from the group consisting of magnetrons or ion beams.

13. The hybrid system of claim 14, wherein said vaporization means is selected from the group consisting of electron beams, lasers or thermal sources.

14. The hybrid system according to claim 13, wherein said electron beam produced plasma is located between said source material and said substrate
